(19) United States
(12) Patent Application Publication
(10) Pub. No.: US 2013/0027107 A1
(43) Pub. Date: Jan. 31, 2013

(54) SIGNAL CONVERSION CIRCUIT, ISOLATOR CIRCUIT INCLUDING THE SAME, AND SIGNAL CONVERSION METHOD

(71) Applicant: Kazunori NOHARA, Shiga (JP)

(72) Inventor: Kazunori NOHARA, Shiga (JP)

(73) Assignee: Renesas Electronics Corporation, Kanagawa (JP)

(21) Appl. No.: 13/525,117

(22) Filed: Jun. 15, 2012

(30) Foreign Application Priority Data
Jul. 25, 2011 (JP) 2011-162012

(51) Int. Cl. H03L 5/00

(52) U.S. Cl. 327/306

(57) ABSTRACT

In one embodiment a signal conversion circuit includes;
first hysteresis comparator configured to receive a differential signal having first and second input signal components, to compare in magnitude between voltages of the first and second input signal components, and to output the comparison result as a first output signal;
a second hysteresis comparator configured to receive the first and second input signal components, to compare in magnitude between the voltages of the first and second input signal components, and to output the comparison result as a second output signal that is an inversion signal of the first output signal; and
a conversion buffer configured to convert the first and second output signals into a single-end signal.

### CROSS-REFERENCE TO RELATED APPLICATIONS

This application is based upon and claims the benefit of priority from Japanese patent application No. 2011-162012, filed on Jul. 25, 2011, the disclosure of which is incorporated herein in its entirety by reference.

### BACKGROUND

The present application relates to a signal conversion circuit, an isolator circuit including the signal conversion circuit, and a signal conversion method.

In industrial equipment and the like, it is necessary to perform digital communication between a high-voltage section and a low-voltage section. In such cases, electric isolation is necessary, and thus an isolator is provided to perform digital communication in a state where current from the high-voltage section is shut off. Some isolators use, for example, capacitive coupling. Note that in the following explanation, an isolator using capacitive coupling is called “capacitive isolator”, and a circuit that transfers a signal using an isolator is called “isolator circuit”.

For example, U.S. Pat. No. 4,835,486 (hereinafter referred to as Literature 1) discloses an isolator circuit including a capacitive isolator. FIG. 7 shows a configuration example of an isolator circuit disclosed in Literature 1. An encoder 102 encodes an analog signal Vi input to a node 103 into a single-ended signal Fi. A differential driver 104 converts the single-ended signal Fi into a differential signal having an in-phase signal component F1 and an opposite-phase signal component F2. The differential signal components F1 and F2 are transferred from a primary side to a secondary side through capacitive isolators 105 and 106 respectively.

The differential signal components P1 and P2 transferred to the secondary side are converted into a single-end signal T by a differential amplifier 107. The single-end signal T is input to comparators 108 and 109. Signals output from the comparators 108 and 109 are converted into signal components R1 and R2 through an RS flip-flop 110. The signal components R1 and R2 are signals that are obtained by reconstructing the differential signal components F1 and F2 respectively. The differential signal having differential signal components R1 and R2 are converted into an output analog signal Vo through a decoder 111.

FIG. 8 shows temporal-waveforms of the signals F1, F2, P1, P2, T and R1 of the isolator circuit 101 shown in FIG. 7. The differential signal components P1 and P2 have the waveforms shown in FIG. 8 because only the edge portions of the differential signal components F1 and F2 pass through the capacitive isolators 105 and 106.

U.S. Pat. No. 7,755,400 (hereinafter referred to as Literature 2) discloses a circuit relating to an isolator in which an AC channel and a DC channel are combined. The circuit disclosed in Literature 2 transfers an input signal to a secondary side through a capacitive isolator. The transferred signal is output through an RS latch.

Japanese Unexamined Patent Application Publication No. 11-317445 (hereinafter referred to as Literature 3) discloses a monoclinic isolator. The isolator disclosed in Literature 3 transfers a pulse signal from a primary side to a secondary side by using a capacitive isolator. The signal that is transferred to the secondary side by the capacitive isolator is converted into the original pulse signal by an edge-triggered pulse reproducing circuit.

Japanese Unexamined Patent Application Publication No. 11-196136 (hereinafter referred to as Literature 4) discloses a signal transmission apparatus using an isolator. The signal transmission apparatus disclosed in Literature 4 transfers an input signal that is encoded by a modulator from a primary side to a secondary side by using an isolator (e.g., capacitive isolator). The signal that is transferred to the secondary side is converted to the encoded input signal by an RS flip-flop. The encoded input signal is demodulated by a synchronous demodulator.

In the isolator circuits disclosed in Literatures 1 to 4, the signal transferred to the secondary side is provided to and converted by an edge-triggered device such as an RS latch and an RS flip-flop. An edge-triggered device outputs an output signal by comparing the voltage of the output signal with the voltage of the input signal. Therefore, in order to output an output signal from an edge-triggered circuit with stability, it is necessary to secure a setup time and a hold time of the input signal (i.e. time periods before and after a change of the input signal during which the input signal is unchanged). When an edge-triggered device receives an input signal with high frequency, there is a possibility that the input signal changes before the setup time or the hold time has elapsed, and thus the output of the edge-triggered device becomes unstable.

From above-described circumstances, the inventor has found out the following problem. In the technique disclosed in Literatures 1 to 4, there is a possibility that the edge-triggered device does not operate properly when the frequency of the signal input to the edge-triggered device is high. As a result, there is a possibility that the isolator circuit cannot operate properly.

### SUMMARY

In one embodiment, a signal conversion circuit includes first and second hysteresis comparators and a conversion buffer. The first hysteresis comparator is configured to receive a differential signal having first and second input signal components, to compare in magnitude between voltages of the first and second input signal components, and to output the comparison result as a first output signal. The second hysteresis comparator is configured to receive the first and second input signal components, to compare in magnitude between the voltages of the first and second input signal components, and to output the comparison result as a second output signal that is an inversion signal of the first output signal. The conversion buffer is configured to convert the first and second output signals into a single-end signal. With this configuration, since the signal conversion circuit outputs the output signal without comparing the input signal with the output signal, the signal conversion circuit can convert a differential signal having a high frequency into a single-end signal and output the single-end signal.

In another embodiment, a signal conversion method includes: outputting, as a first output signal, a result of a magnitude comparison between voltages of first and second input signal components of a differential signal; and outputting, as a second output signal that is an inversion signal of the first output signal, a result of a magnitude comparison between the voltages of the first and second input signal components; and converting the first and second output signals into a single-end signal. With this method, it is possible to convert a differential signal having a high frequency into a single-end signal and output the single-end signal because the output signal is output without comparing the input signal with the output signal.

According to said embodiments, it is possible to provide a signal conversion circuit, an isolator circuit including the signal conversion circuit, and a signal conversion method, capable of converting a differential signal having a high frequency into a single-end signal.

### BRIEF DESCRIPTION OF THE DRAWINGS

The above and other aspects, advantages and features will be more apparent from the following description of certain embodiments taken in conjunction with the accompanying drawings, in which:

FIG. 1 is an overall view showing a configuration example of a signal conversion circuit according to a first embodiment;

FIG. 2 is a circuit diagram showing a specific configuration example of a signal conversion circuit according to a first embodiment;

FIG. 3 is a timing chart showing temporal-waveforms at nodes in a signal conversion circuit according to a first embodiment;

FIG. 4 is a timing chart for explaining temporal-waveforms in a signal conversion circuit according to a first embodiment;

FIG. 5 is an overall view showing a configuration example of an isolator circuit according to a second embodiment;

FIG. 6 is a timing chart showing temporal-waveforms at nodes in an isolator circuit according to a second embodiment;

FIG. 7 shows an isolator according to a related art; and

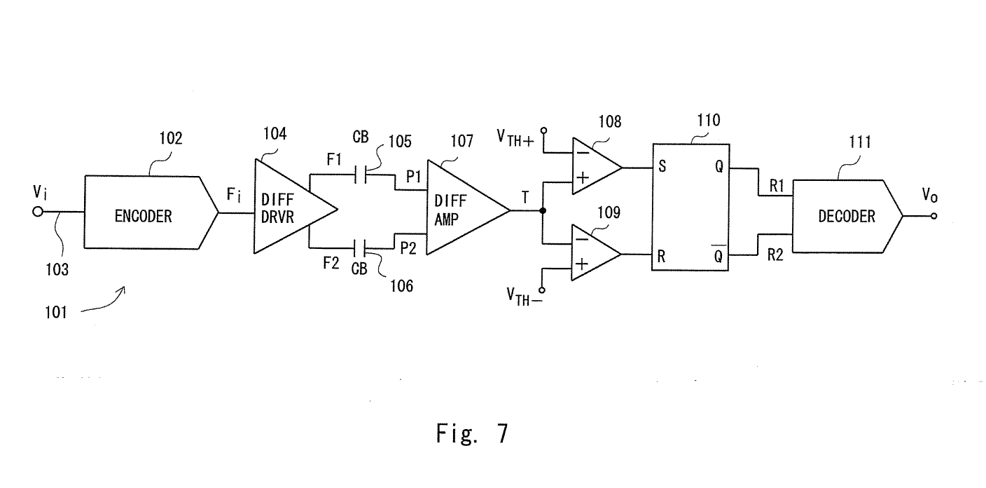

FIG. 8 is a timing chart showing a temporal-waveform at each node in an isolator according to a related art.

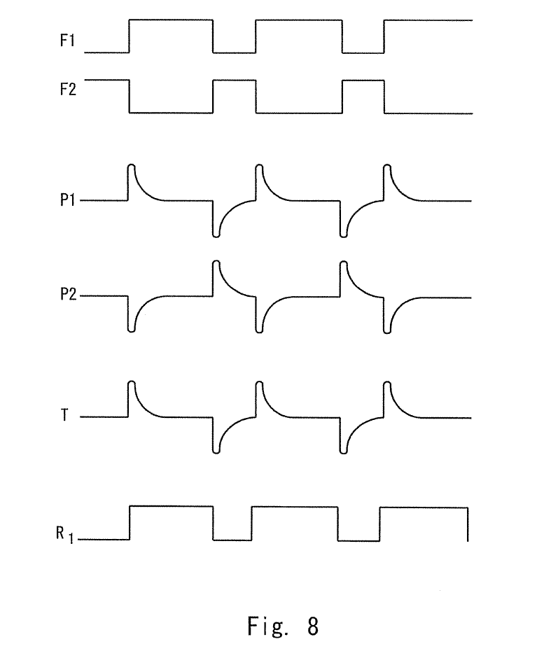

### DETAILED DESCRIPTION

### First Embodiment

A signal conversion circuit according to this embodiment includes two hysteresis comparators and a conversion buffer to which the outputs of the hysteresis comparators are input. The two hysteresis comparators output a differential signal having two signal components whose phases are opposite to each other. The conversion buffer converts the differential signal into a single-end signal according to the logic level of the differential signal. This signal conversion circuit can properly convert a differential signal into a single-end signal even when the differential signal have a high frequency because it converts the differential signal without using any edge-triggered circuit such as a flip-flop. This embodiment is explained hereinafter with reference to the drawings.

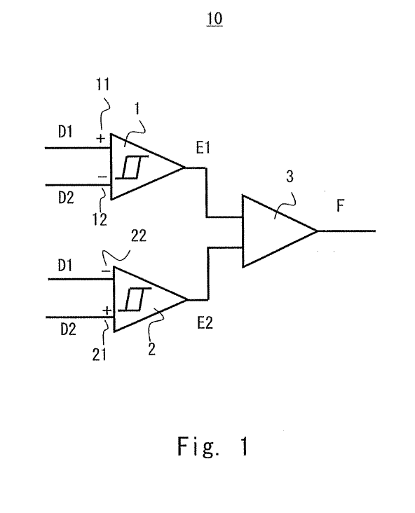

FIG. 1 is an overall view showing a configuration example of a signal conversion circuit 10. The signal conversion circuit 10 includes hysteresis comparators 1 and 2 and a differential-single conversion buffer 3.

The hysteresis comparator 1 includes a noninverting input terminal 11 and an inverting input terminal 12. A signal D1 is input to the noninverting input terminal 11 and a signal D2, which is an inversion signal of the signal D1, is input to the inverting input terminal 12. In other words, the signal D1 and D2 are signal components of a differential signal.

The hysteresis comparator 1 outputs a signal E1 according to the input signals D1 and D2. Hereinafter, the voltage of the signal D1 is represented by V1 and the voltage of the signal D2 is represented by V2. The hysteresis comparator 1 outputs the signal E1, which is a digital signal, by comparing a difference voltage V1−V2 with first and second threshold voltages. Note that the first threshold voltage is represented by A1 and the second threshold voltage is represented by A2.

The hysteresis comparator 2 is a circuit having a similar configuration to that of the hysteresis comparator 1. The hysteresis comparator 2 includes a noninverting input terminal 21 and an inverting input terminal 22. The signal D2 is input to the noninverting input terminal 21 and the signal D1 is input to the inverting input terminal 22. The hysteresis comparator 2 outputs a signal E2 according to the input signals D1 and D2. More specifically, the hysteresis comparator 2 outputs the signal E2, which is a digital signal, by comparing a difference voltage V2−V1 with the first and second threshold voltages A1 and A2.

Note that the signal components that are input to the noninverting input terminal 21 and the inverting input terminal 22 of the hysteresis comparator 2 are opposite to the signals that are input to the noninverting input terminal 11 and the inverting input terminal 12 of the hysteresis comparator 1. Therefore, the signals E1 and E2, which are output by the hysteresis comparators 1 and 2, are differential signal components whose phases are substantially reversed from each other. Note that the phase, the amplitude, and the like of the signal E2 can change from the inversion signal of the signal E1 within an error range or a permissible range. This is also true for other differential signals.

The signals E1 and E2 are input to the differential-single conversion buffer 3. The differential-single conversion buffer 3 outputs a single-end signal F according to the logic level of the differential signal components E1 and E2.

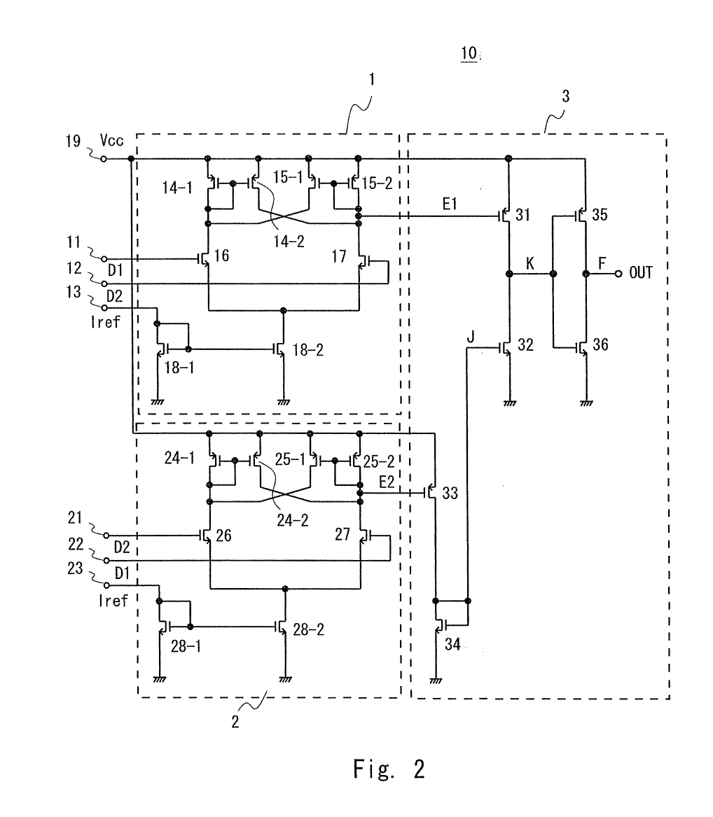

Next, a specific configuration of the signal conversion circuit 10 is explained. FIG. 2 is a circuit diagram showing a specific example of the signal conversion circuit 10.

In FIG. 2, a constant voltage source (not shown) is connected to a power supply voltage terminal 19, and a constant voltage Vcc is thereby supplied from the power supply voltage terminal 19. The constant voltage Vcc is a common driving power supply for the hysteresis comparators 1 and 2 and the differential-single conversion buffer 3.

Firstly, a specific configuration of the hysteresis comparator 1 is explained. The hysteresis comparator 1 includes a noninverting input terminal 11, an inverting input terminal 12, a reference current terminal 13, and MOS (Metal-Oxide-Semiconductor) transistors 14-1, 14-2, 15-1, 15-2, 16, 17, 18-1 and 18-2. The MOS transistors 14-1, 14-2, 15-1 and 15-2 are Pch-MOSFETs (Metal-Oxide-Semiconductor Field-Effect Transistors) and the MOS transistors 16, 17, 18-1 and 18-2 are Nch-MOSFETs. A reference current source (not shown) is connected to the reference current terminal 13, and a reference current Iref is thereby supplied to the reference current terminal 13.

The sources of the MOS transistors 14-1, 14-2, 15-1 and 15-2 are connected to the power supply voltage terminal 19, and the constant voltage Vcc is thereby supplied to these sources.

The MOS transistors 14-1 and 14-2 have a current-mirror configuration. More specifically, the gates of the MOS transistors 14-1 and 14-2 are connected to each other, and the output from the drain of the MOS transistor 14-1 is input to the gates of the MOS transistors 14-1 and 14-2. That is, in the MOS transistor 14-1, the gate and the drain are connected to each other. The MOS transistors 15-1 and 15-2 have a similar current-mirror configuration. Further, the size of the MOS transistor 14-2 is larger than that of the MOS transistor 14-1, and the size of the MOS transistor 15-1 is larger than that of the MOS transistor 15-2. By using this configuration, it is possible to give a hysteresis characteristic to the hysteresis comparator.

The drains of the MOS transistors 14-1 and 15-1 are connected to the drain of the MOS transistor 16. The drains of the MOS transistors 14-2 and 15-2 are connected to the drain of the MOS transistor 17.

Note that the output signal E1 of the MOS transistor 15-2 is input to the gate of the MOS transistor 31 of the differential-single conversion buffer 3. The operation of the MOS transistor 31 is explained later.

The gate of the MOS transistor 16 is connected to the noninverting input terminal 11, and the signal D1 is thereby input to the gate. The gate of the MOS transistor 17 is connected to the inverting input terminal 12, and the signal D2 is thereby input to the gate. The sources of the MOS transistors 16 and 17 are connected to the drain of the MOS transistor 18-2.

The MOS transistors 18-1 and 18-2 have a current-mirror configuration. More specifically, the source of the MOS transistor 18-1 is connected to the reference current terminal 13, and the reference current Iref is thereby supplied to the source. The drain and the gate of the MOS transistor 18-1 are connected to each other and also connected to the gate of the MOS transistor 18-2. The sources of the MOS transistors 18-1 and 18-2 are connected to the ground. With the above-described configuration, a current is supplied to the MOS transistor 18-2, which is the tail current source of the hysteresis comparator 1.

With the above-described configuration, even when the voltage V1 of the signal D1 and the voltage V2 of the signal D2 become equal to each other, the logic level of the signal E does not change immediately. That is, it is possible to give hysteresis to the hysteresis comparator. That is, it is possible to secure the hysteresis characteristic of the hysteresis comparator 1. The details of this feature are explained later.

The hysteresis comparator 2 includes a noninverting input terminal 21, an inverting input terminal 22, a reference current terminal 23, and MOS transistors 24-1, 24-2, 25-1, 25-2, 26, 27, 28-1 and 28-2. The MOS transistors 24-1, 24-2, 25-1 and 25-2 are Pch-MOSFETs and the MOS transistors 26, 27, 28-1 and 28-2 are Nch-MOSFETs.

The output signal E2 of the MOS transistor 25-2 is input to the gate of the MOS transistor 33 of the differential-single conversion buffer 3. The remaining parts of the specific configuration of the hysteresis comparator 2 are similar to those of the hysteresis comparator 1, and therefore their explanation is omitted.

Next, a specific configuration of the differential-single conversion buffer 3 is explained. The differential-single conversion buffer 3 includes MOS transistors 31, 32, 33, 34, 35 and 36. The MOS transistors 31, 33 and 35 are Pch-MOSFETs (PMOS transistors) and the MOS transistors 32, 34 and 36 are Nch-MOSFETs (NMOS transistors). Note that in the MOS transistors 31 and 32, the PMOS transistor is connected on the power supply voltage side and the NMOS transistor is connected on the ground side. That is, the MOS transistors 31 and 32 form a CMOS circuit. This is also true for the MOS transistors 33 and 34, and the MOS transistors 35 and 36.

The source of the MOS transistor 31 is connected to the power supply voltage terminal 19, and the constant voltage Vcc is thereby supplied to the source. As described previously, the output signal E1 of the MOS transistor 15-2 is input to the gate of the MOS transistor 31. An output signal K from the drain of the MOS transistor 31 is input to the drain of the MOS transistor 32 and the gates of the MOS transistors 35 and 36.

The gate of the MOS transistor 32 is connected to the drain of the MOS transistor 33. The source of the MOS transistor 32 is connected to the ground.

The source of the MOS transistor 33 is connected to the power supply voltage terminal 19, and the constant voltage Vcc is thereby supplied to the source. As described previously, the output signal E2 of the MOS transistor 25-2 is input to the gate of the MOS transistor 33. An output signal J from the drain of the MOS transistor 33 is input to the drain of the MOS transistor 34 and the gate of the MOS transistor 32. The source of the MOS transistor 34 is connected to the ground.

The source of the MOS transistor 35 is connected to the power supply voltage terminal 19, and the constant voltage Vcc is thereby supplied to the source. As described previously, the output signal K of the MOS transistor 31 is input to the gate of the MOS transistor 35. The output signal F from the drain of the MOS transistor 35 is output as the output of the differential-single conversion buffer 3. Further, the output signal F is input to the drain of the MOS transistor 36.

As described previously, the output signal K of the MOS transistor 31 is input to the gate of the MOS transistor 36. The source of the MOS transistor 36 is connected to the ground.

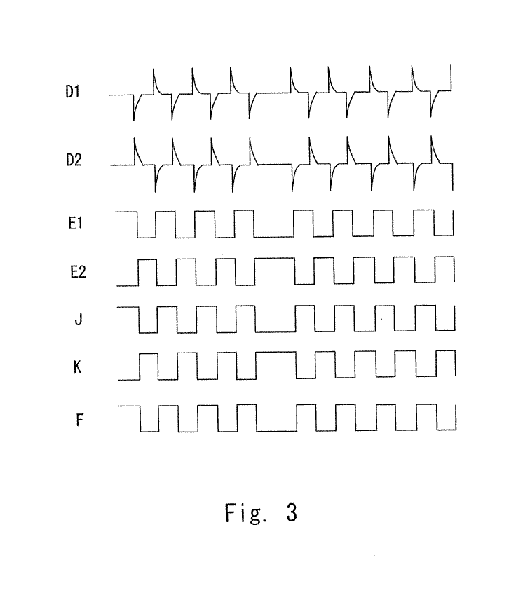

An operation of the signal conversion circuit 10 shown in FIG. 2 is explained hereinafter with reference to FIG. 3. FIG. 3 shows an example of temporal-waveforms at nodes of the signal conversion circuit 10.

An edge signal D1 shown in FIG. 3 is input to the noninverting input terminal 11 and the inverting input terminal 22. An edge signal D2 shown in FIG. 3 is input to the inverting input terminal 12 and the noninverting input terminal 21. Note that the edge signals D1 and D2 are signals indicating rising and falling edges of a signal. In this manner, the signals D1 and D2, which are differential signal components, are connected to mutually-opposite input terminals of the hysteresis comparators 1 and 2. As a result, the hysteresis comparators 1 and 2 output digital signals E1 and E2 having opposite phases.

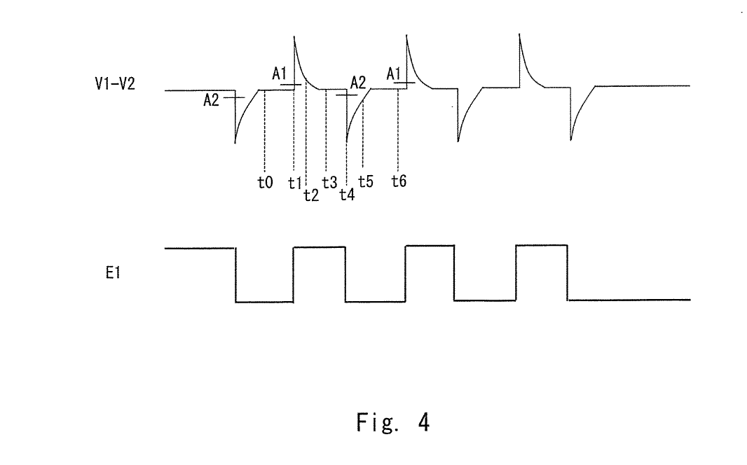

Details of the operation performed by the hysteresis comparator 1 in which the edge signals D1 and D2 are converted into the digital signal E1 are explained hereinafter with reference to FIG. 4. FIG. 4 shows a temporal-waveform of the difference voltage V1−V2 and a temporal-waveform of the signal E1.

At an initial time t0, the value of the difference voltage V1−V2 is zero. At this point, the logic level of the signal E1 is

At a time t1, the waveform of the difference voltage V1−V2 becomes a raised-edge state. In other words, the voltage V1 is sufficiently higher than the voltage V2. When the difference voltage V1−V2 exceeds the first threshold voltage A1, the MOS transistor 16 is turned on and the MOS transistor 17 is turned off in the hysteresis comparator 1. Since the MOS transistor 17 is turned off, the MOS transistors 15-1 and 15-2 are turned off. At this point, the current output from the source of the MOS transistor 14-2 is supplied to the gate of the MOS transistor 31. As a result, the voltage value of the signal E1 becomes substantially equal to Vcc and the signal E1 thereby takes on a logic value “1”.

Note that the first threshold voltage A1 has a positive value that is sufficiently smaller than the maximum value (value of the end point of the rising edge) of the difference voltage V1−V2.

At a time t2, the difference voltage V1−V2 approaches zero from the raised-edge state. More specifically, the voltage V1 approaches a constant voltage value (e.g., zero) from the raised-edge state, while the voltage V2 approaches the constant voltage value from the lowered-edge state.

At a time t3, the difference voltage V1−V2 has a value zero. That is, the voltage V1, which is applied to the gate of the MOS transistor 16, is equal to the voltage V2, which is applied to the gate of the MOS transistor 17. For example, when the MOS transistors 16 and 17 have the same gate length and the same gate width, the currents output from the MOS transistors 16 and 17 have the same value.

At this point, the MOS transistors 15-1 and 15-2 are maintained in the Off state. Further, since the size of the MOS transistor 14-2 is larger than the size of the MOS transistor 14-1, the drain current of the MOS transistor 14-2 is larger than the drain current of the MOS transistor 14-1. Further, the drain currents of the MOS transistors 16 and 17 are equal to each other. Therefore, since an electrical charge is accumulated in the drain of the MOS transistor 17, the drain voltage of the MOS transistor 17 is maintained at the High level. Accordingly, even when the difference voltage V1−V2 becomes zero, the logic level of the signal E1 does not becomes “0” and is kept at “1”. That is, it is possible to give a hysteresis characteristic to the hysteresis comparator.

At a time t4, the difference voltage V1−V2 becomes a lowered-edge state. In other words , the voltage V1 is sufficiently lower than the voltage V2. In this state, when the difference voltage V1−V2 falls below the second threshold voltage A2, the MOS transistor 17 is turned on and the MOS transistor 16 is turned off. Since the MOS transistor 16 is turned off, the MOS transistors 14-1 and 14-2 are turned off. Since the MOS transistor 17 is turned on, the drain voltage of the MOS transistor 17 becomes sufficiently low and the logic level of the signal E1 thereby becomes “0”.

Note that the second threshold voltage A2 has a negative value that is sufficiently larger than the minimum value (value of the end point of the falling edge) of the difference voltage V1−V2.

At a time t5, the difference voltage V1−V2 approaches zero from the lowered-edge state. That is, the voltage V1 approaches the constant voltage value from the lowered-edge state, while the voltage V2 approaches the constant voltage value from the raised-edge state.

At a time t6, the difference voltage V1−V2 has a value zero. Note that the same voltage is applied to the gates of the MOS transistors 16 and 17. At this point, the MOS transistors 14-1 and 14-2 are maintained in the Off state. Further, since the size of the MOS transistor 15-1 is larger than the size of the MOS transistor 15-2, the drain current of the MOS transistor 15-1 is larger than the drain current of the MOS transistor 15-2. Further, the drain currents of the MOS transistors 16 and 17 are equal to each other. Therefore, since an electrical charge is accumulated in the drain of the MOS transistor 16, the drain voltage of the MOS transistor 16 is maintained at the High level and the drain voltage of the MOS transistor 17 is maintained at the Low level. As a result, the logic level of the signal E1 does not becomes “1” and is kept at

Through the operation described above, the hysteresis comparator 1 converts the edge signals D1 and D2 into the digital signal E1. Similarly, the hysteresis comparator 2 converts the edge signals D1 and D2 into the digital signal E2. Note that the first threshold voltage A1 is determined based on the ratio between the currents fed by the MOS transistors 14-1 and 14-2. The second threshold voltage A2 is determined based on the ratio between the currents fed by the MOS transistors 15-1 and 15-2.

Note that the ratio between the currents fed by the MOS transistors 14-1 and 14-2 or the ratio between the currents fed by the MOS transistors 15-1 and 15-2 changes depending on the size of each MOS transistor, i.e., depending of the gate length and gate width of each MOS transistor. For example, when the gate length of the MOS transistor 14-2 is equal to that of the MOS transistor 14-1 and the gate width of the MOS transistor 14-2 is twice as long as the gate width of the MOS transistor 14-1, the MOS transistor 14-2 feeds a current that is twice as large as the current fed by the MOS transistor 14-1.

Referring to FIG. 3 again, an operation of the signal conversion circuit 10 shown in FIG. 2 is explained hereinafter. The output signal E2 is input to the gate of the MOS transistor 32 through the MOS transistors 33 and 34. Note that when the logic level of the signal E2 is “1”, the MOS transistor 33 does not feed any current (does not operate), whereas when the logic level of the signal E2 is “0”, the MOS transistor 33 feed a current. As a result, a signal J, which has a reversed phase to that of the signal E2, is input to the gate of the MOS transistor 32. That is, the MOS transistors 33 and 34 function as a phase inversion unit that outputs a signal whose phase is reversed from the phase of signal E2.

The signal E1 is input to the gate of the MOS transistor 31 and thereby drives the MOS transistor 31. That is, when the logic level of the signal E1 is “1”, the MOS transistor 31 does not feed any current, whereas when the logic level of the signal E1 is “0”, the MOS transistor 31 feeds a current. As a result, a signal K having an opposite phase to that of the signal E1 is output from the MOS transistor 31. Further, the signal J is in phase with the signal E1 and drives the MOS transistor 32.

Note that the MOS transistors 31 and 32 form a buffer and output the signal K, which is substantially in phase with the signal E2, according to the signal E1 and the signal J. This signal K is inverted through an inverter formed by the MOS transistors 35 and 36, and the inverted signal is output as a signal F. The MOS transistor 35 changes whether the current is output or not according to the logic level of the signal K. Note that signal F is a single-end signal.

Through the operation described above, the signal conversion circuit 10 converts the edge signals D1 and D2, which are differential signal components, into the single-end signal F. Note that the signal conversion circuit 10 enables the circuit to operate at a higher speed by using the hysteresis comparators 1 and 2, which operate according to the voltage difference between signals, and the differential-single conversion buffer 3, which operates according to the logic level of a signal.

When a differential signal is converted by using an edge-triggered device such as an RS flip-flop, that device outputs an output signal by comparing the voltage of the output signal with the voltage of the input signal. Therefore, as described previously, it is necessary to secure a setup time and a hold time of the input signal, which are time periods before and after a change of the input signal during which the input signal is unchanged. In such a case, when the frequency of the input signal is high, there is a possibility that the input signal changes before the setup time or the hold time has elapsed and thus the output becomes unstable. As a result, there is a possibility that the circuit cannot operate properly.

The signal conversion circuit 10 according to this embodiment does not adopt the configuration in which the voltages of the output signal and the input signal are compared to output the output signal. The hysteresis comparators 1 and 2 operate according to the voltage difference between the input signals D1 and D2. Further, the differential-single conversion buffer operates according to the logic levels of the input signals E1 and E2. With this configuration, the signal conversion circuit 10 can operate properly even when the frequency of the input signal is high.

Note that since the hysteresis comparators 1 and 2 and the differential-single conversion buffer 3 have a common driving power supply, it is possible to make the configuration of the signal conversion circuit 10 simpler.

Note that the input signal to the hysteresis comparators 1 and 2 is not limited to the edge signals D1 and D2 shown in FIG. 3. For example, an edge signal having a different amplitude may be input to the noninverting input terminal 21 of the hysteresis comparator 2, provided that the edge signal is substantially in phase with the signal D2. In this case, an inversion signal of that edge signal is input to the inverting input terminal 22. That is, a differential signal-is input to the hysteresis comparator 2. In this configuration, by changing the threshold voltage in the hysteresis comparator 2 as appropriate, the signal conversion circuit 10 can perform a similar operation to the above-described operation.

Further, the input signal to the hysteresis comparators 1 and 2 is not limited to edge signals. That is, other types of signals including a pulse signal may be also applied. The input signal may be either an AC signal or a DC signal.

Other configurations may be also employed for the hysteresis comparators 1 and 2. In such cases, when signals D1 and D2, which are differential signal components, are input to the hysteresis comparator 1, the hysteresis comparator 1 compares the magnitudes of the voltages of the signals D1 and D2 and outputs the comparison result as the signal E1. When the signals D1 and D2, which are differential signal components, are input to the hysteresis comparator 2, the hysteresis comparator 2 compares the magnitudes of the voltages of the signals D1 and D2 and outputs the comparison result as the signal E2, which is an inversion signal of the signal E1. As for the differential-single conversion buffer 3, various other configurations may be employed, provided the differential-single conversion buffer can perform a similar operation to that of this embodiment.

### Second Embodiment

An isolator circuit according to this embodiment includes a signal conversion circuit described above in the first embodiment, and is an isolator circuit configured to transfer a digital signal from a primary side to a secondary side. With this isolator circuit, it is possible to transfer a signal having a high frequency. Further, since the capacitance value of the capacitive isolator(s) configured to transfer a signal from the primary side to the secondary side can be reduced, it is possible to reduce the size of the capacitive isolator(s). That is, it is possible to reduce the overall size of the isolator circuit. This embodiment is explained hereinafter with reference to the drawings.

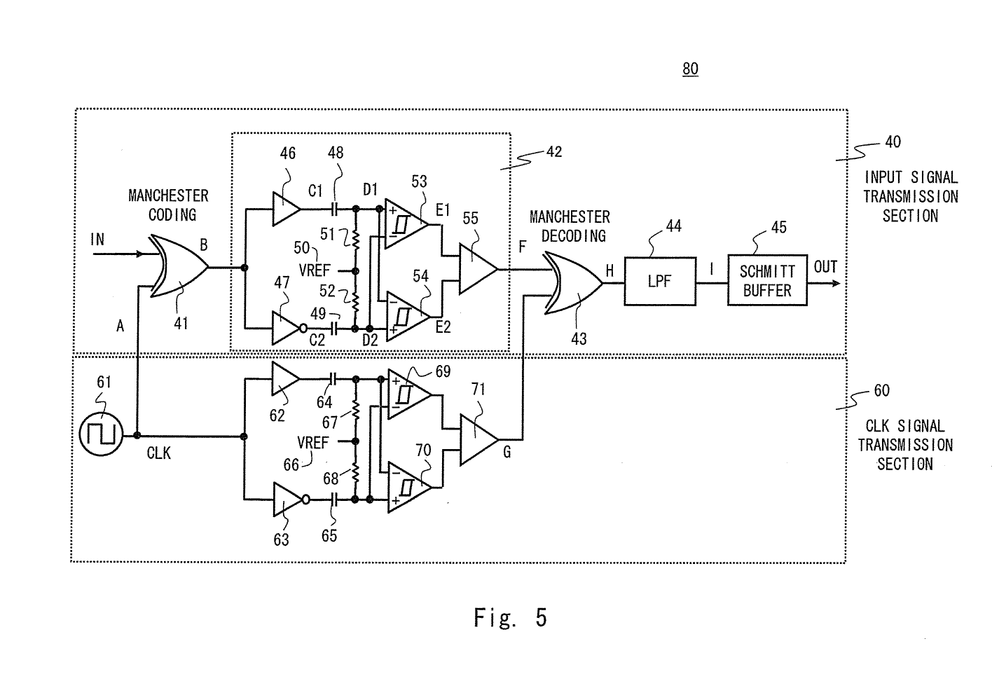

FIG. 5 shows an overall view of an isolator circuit according to this embodiment. An isolator circuit 80 is divided broadly into two sections, i.e., an input signal transmission section 40 and a CLK (clock) signal transmission section 60. Note that in FIG. 5, the left side of capacitive isolators 48, 49, 64 and 65 is a primary-side circuit (digital signal transmission side of the circuit), and the right side thereof is a secondary-side circuit (digital signal reception side of the circuit).

The input signal transmission section 40 transfers a supplied digital input signal (transmission signal) IN from the primary side to the secondary side. The input signal transmission section 40 includes an XOR element (exclusive-OR operation circuit) 41, a composite signal transmission unit 42, an XOR element 43, an LPF (low-pass filter) 44 and a Schmitt buffer 45.

In the XOR element 41, the digital input signal IN is input to a first input terminal and a CLK signal A, which is output from a CLK oscillator 61, is input to a second input terminal. The XOR element 41 outputs a composite signal B to the composite signal transmission unit 42 according to the digital input signal IN and the CLK signal A.

The composite signal transmission unit 42 transfers the input composite signal B from the primary side to the secondary side. The composite signal transmission unit 42 includes a buffer 46, an inverter 47, capacitive isolators 48 and 49, a reference voltage source 50, resistors 51 and 52, hysteresis compactors 53 and 54, and a differential-single conversion buffer 55. Each of the capacitive isolators 48 and 49 includes, for example, a capacitive element such as a capacitor.

The buffer 46 outputs the composite signal B to the capacitive isolator 48 as a signal C1 without making any change to the composite signal B. The inverter 47 outputs a signal C2, which is obtained by inverting the composite signal B, to the capacitive isolator 49. That is, the buffer 46 and the inverter 47 function as a conversion unit that converts the composite signal B into a differential signal having a signal component C1 and a signal component C2.

The capacitive isolator 48 converts the signal C1 supplied from the primary side into an edge signal D1 indicating rising and falling edges (signal changing points) of the signal C1 and transfers the edge signal D1 to the secondary side. Similarly, the capacitive isolator 49 converts the signal C2 supplied from the primary side into an edge signal D2 and transfers the edge signal D2 to the secondary side. Note that the primary side and the secondary side are electrically isolated from each other. The edge signals D1 and D2 are differential signal components.

The signal D1 output from the capacitive isolator 48 is input to a noninverting input terminal of the hysteresis comparator 53 and an inverting input terminal of the hysteresis comparator 54. The signal D2 output from the capacitive isolator 49 is input to an inverting input terminal of the hysteresis comparator 53 and a noninverting input terminal of the hysteresis comparator 54. Note that a reference voltage Vref is output from the reference voltage source 50 to the nodes for transferring the signals D1 and D2, through the resistors 51 and 52. The DC bias level on the secondary side is determined based on this reference voltage Vref.

As described above, the edge signals D1 and D2 are input to the noninverting input terminal and the inverting input terminal, respectively, of the hysteresis comparator 53. The hysteresis comparator 53 outputs a digital signal E1 to the differential-single conversion buffer 55 according to the edge signals D1 and D2.

As described above, the edge signals D1 and D2 are input to the inverting input terminal and the noninverting input terminal, respectively, of the hysteresis comparator 54. The hysteresis comparator 54 outputs a digital signal E2 to the differential-single conversion buffer 55 according to the edge signals D1 and D2.

The differential-single conversion buffer 55 outputs a single-end signal F to the XOR element 43 according to the digital signals E1 and E2.

The output signal F of the differential-single conversion buffer 55 and a CLK signal G output from the CLK signal transmission section 60 are input to the XOR element 43. The XOR element 43 outputs a signal H to the LPF 44 according to the output signal F and the CLK signal G.

The LPF 44 outputs a signal I, which is the low-frequency component of the signal H, to the Schmitt buffer 45.

The Schmitt buffer 45 outputs a digital signal OUT, which is substantially identical to the original digital input signal IN, according to the input signal I.

The CLK signal transmission section 60 transfers the CLK signal A from the primary side to the secondary side. The CLK signal transmission section 60 includes a CLK oscillator 61, a buffer 62, an inverter 63, capacitive isolators 64 and 65, a reference voltage source 66, resistors 67 and 68, hysteresis compactors 69 and 70, and a differential-single conversion buffer 71.

The CLK oscillator 61 outputs a CLK signal A (oscillation output signal) to the XOR element 41, the buffer 62, and the inverter 63. The configuration of each of the other components is similar to that of the above-described composite signal transmission unit 42, and therefore their explanation is omitted.

Note that the specific configurations of the hysteresis compactors 53 and 54 and the differential-single conversion buffer 55 are similar to those described above in the first embodiment. The specific configurations of the hysteresis compactors 69 and 70 and the differential-single conversion buffer 71 are also similar to those described above in the first embodiment.

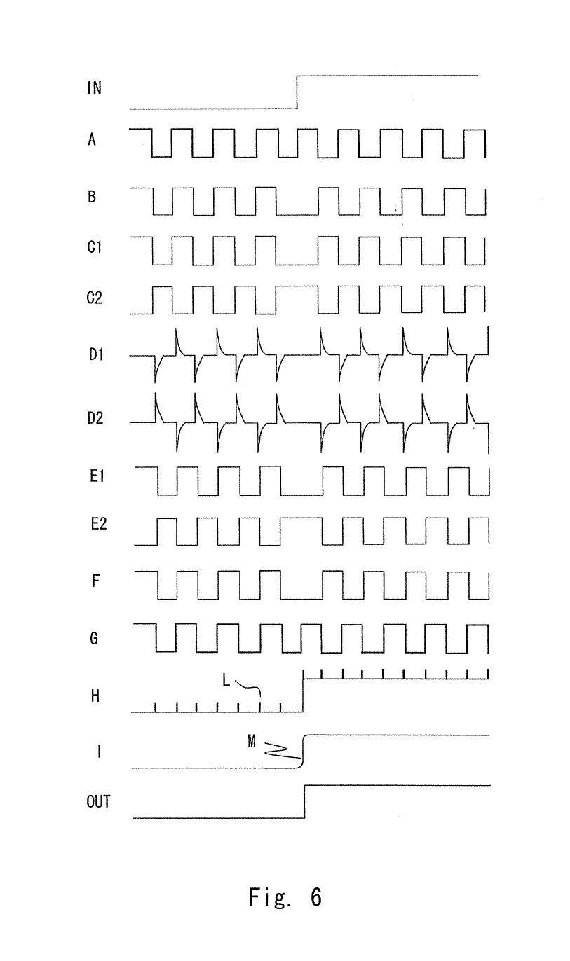

An operation of the isolator circuit 80 shown in FIG. 5 is explained hereinafter with reference to FIG. 6. FIG. 6 shows an example of temporal-waveforms at nodes in the isolator circuit 80. Note that the signals D1, D2, E1 and E2 are the same signals as the signals D1, D2, E1 and E2 shown in FIG. 3.

Firstly, the digital input signal IN is input to the XOR element 41 of the isolator circuit 80. In FIG. 6, the supplied digital input signal IN is a DC signal. The XOR element 41 generates a composite signal B shown in FIG. 6 by encoding the supplied digital input signal IN and the CLK signal A output from the CLK oscillator 61 into Manchester code. That is, the XOR element 41 functions as an encoder. Note that the composite signal B is a digital signal.

The Manchester coding means an encoding technique in which “1” and “0” of the original digital signal are encoded into “10” and “01” respectively, and is a technique that is commonly used in wired LANs (IEEE802.3). Since the digital input signal IN is a DC signal, the digital input signal IN is converted into a pulse string having a frequency equal to the oscillating frequency of the CLK oscillator 61 by the Manchester coding.

Next, the buffer 46 and the inverter 47 convert the composite signal B, which is obtained by the Manchester coding, into signals C1 and C2 as shown in FIG. 6. The signals C1 and C2 are differential signal components. By converting into the differential signal in this manner, it is possible to secure the robustness of the composite signal B against the common-mode noise.

The signal C1 is input to the capacitive isolator 48. The capacitive isolator 48 generates an edge signal D1, which is obtained by extracting only rising and falling edges from the signal C1, and the signal D1 is transferred to the secondary side. Similarly, the capacitive isolator 49 generates an edge signal D2 from the signal C2 and transfers the signal D2 to the secondary side. The edge signals D1 and D2 are input to the hysteresis comparators 53 and 54.

The hysteresis comparators 53 and 54 detect rising and falling edges of the signals D1 and D2 and thereby generate digital signals E1 and E2 shown in FIG. 6.

The digital signals E1 and E2 are input to the differential-single conversion buffer 55 and thereby converted from the differential signal into a single-end signal F. This signal F is substantially identical to the composite signal B. That means that the composite signal B is transferred through the composite signal transmission unit 42. The specific operations of the hysteresis compactors 53 and 54 and the differential-single conversion buffer 55 are similar to those described above in the first embodiment.

Note that the CLK signal A, which is output by the CLK oscillator 61, is transferred by the CLK signal transmission section 60 in a similar manner to the transmission performed by the composite signal transmission unit 42. The transferred CLK signal G is input to the XOR element 43. The CLK signal G is substantially the same signal as the CLK signal A.

In the XOR element 43, an exclusive-OR operation of the signal F and the CLK signal G is performed so that they are decoded from the Manchester code to the original signal. That is, the XOR element 43 functions as a decoder. FIG. 6 shows a waveform of the signal H, which is obtained by the Manchester decoding and output from the XOR element 43.

Note that in the signal H, spike noises L, which are caused by the phase difference between the CLK signal A used for the encoding and the CLK signal G used for the decoding, appear in a superimposed state.

The LPF 44 cuts off the noises L by using a low-pass filter and thereby generates a waveform as shown as a signal I in FIG. 6. Therefore, the maximum bit-rate of the digital input signal IN is limited by the cut-off frequency of the LPF 44. Note that the edge portion M of the signal I is blunted due to the effect of the low-pass filter as shown in FIG. 6.

The signal I is input to the Schmitt buffer 45. Note that the Schmitt buffer 45 removes the noises that cannot be completely removed by the LPF 44. Further, the Schmitt buffer 45 shapes the edge portion M of the signal I, which is blunted by the LPF 44, into a sharp edge shape. Through the process described above, the digital signal OUT, which is output by the Schmitt buffer 45 according to the signal I, becomes substantially the same signal as the originally-supplied digital input signal IN. In this manner, the digital input signal IN is reproduced in the secondary side.

The isolator circuit 80 shown above provides the following advantageous effects.

In the isolator circuit 80, the output signals D1 and D2 of the capacitive isolators 48 and 49 are converted into the signal F by the hysteresis comparators 53 and 54 and the differential-single conversion buffer 55. Similarly, the output signals of the capacitive isolators 64 and 65 are converted into the signal G by the hysteresis comparators 69 and 70 and the differential-single conversion buffer 71. No edge-triggered device is used in these signal conversions. Therefore, as described above in the first embodiment, the isolator circuit 80 can operate at a higher speed (i.e., signal can be transferred at a higher speed). That is, it is possible to increase the frequency of the CLK signal A.

In addition, since there is no need to lower the frequency of the CLK signal A, there is no need to increase the capacitance value of the capacitive isolators 48, 49, 64 and 65. Therefore, it is possible to minimize the size of the capacitive isolators 48, 49, 64 and 65. As a result, there is a new advantageous effect that the size of the isolator circuit 80 can be minimized.

The isolator circuit 80 shown in FIG. 5 can transfer a digital signal from the primary side to the secondary side through the capacitive isolator, even when the digital signal is a DC digital input signal IN in which there is no change in the signal, by using Manchester coding. This is because since the digital input signal IN is converted into a pulse string having a frequency equal to the frequency of the CLK signal A by using Manchester coding, it can be transferred to the capacitive isolators 48 and 49.

For example, assume a case where a capacitive isolator is used for the transmission of an input signal without encoding and decoding the input signal. When the input signal has a low frequency close to DC, it is necessary to increase the capacitance value of the capacitive isolator in order to enable the input signal to pass through the capacitive isolator. Further, it is impossible to pass a DC input signal through the capacitive isolator.

As described previously, the isolator circuit 80 according to this embodiment can transfer a DC signal without increasing the capacitance value of the capacitive isolator.

Further, in the isolator circuit 80, after the single-end composite signal B is converted into the differential signal having signal components C1 and C2, the signal components C1 and C2 are transferred to their respective capacitive isolators 48 and 49. In this way, it is possible to improve the robustness of the transmission signal against the common-mode noise. Similarly, the signal between the outputs of the capacitive isolators 48 and 49 and the inputs of the hysteresis comparators 53 and 54 is not a single-end signal but is a differential signal, so that the robustness of the signal against the common-mode noise can be further improved. The above-described advantageous effects are also achieved in the transmission of the CLK signal.

Further, the edge signals D1 and D2 are input to mutually-opposite terminals of the hysteresis comparators 53 and 54. That is, the edge signals D1 and D2 are connected in a “cross” configuration. By detecting rising and falling edges of edge signals by using different hysteresis comparators in this manner, it is possible to achieve an excellent rising-and-falling differential balance. Therefore, it is possible to improve the robustness of the signal against the common-mode noise. This is also true for the hysteresis comparators 69 and 70.

Further, by decoding the Manchester code and then supplying the decoded signal to the LPF 44 and the Schmitt buffer 45, it is possible to remove the noises that are caused by the phase difference between the CLK signal A and the CLK signal G. Therefore, there is no need to provide any component that synchronize the input signal IN with the CLK signal A, thus achieving an advantageous effect that the isolator circuit 80 can be simplified.

The isolator circuit 80 according to this embodiment can be applied as appropriate to signal transmission apparatuses using an isolator. For example, it can be used in fields in which precise handling of electricity is essential, such as a medical field and a measurement field. It can be also applied to other fields including a communication field.

Note that the present invention is not limited to the above-described embodiments, and they can be modified as appropriate without departing from the scope and spirit of the present invention. For example, each of the hysteresis comparators land 2 and the differential-single conversion buffer 3 may be formed by using transistors other than MOSFETs, provided that they perform similar operations. Alternatively, elements other than transistors may be also used, provided that no edge-triggered device is used. For the hysteresis comparators 1 and 2 and the differential-single conversion buffer 3, the common driving power supply and the reference current supply do not necessarily have to be used.

In the isolator circuit 80 according to the second embodiment, the CLK signal transmission section 60 may not be provided and synchronized CLK signals output from other CLK oscillators may be input to the XOR elements 41 and 43. Even in such a configuration, the XOR elements 41 and 43 can perform Manchester encoding and decoding, thus enabling the isolator circuit 80 to operate at a higher speed. However, in such a case, it is necessary to provide a circuit that is used to synchronize the CLK signal output from other CLK oscillators. In order to reduce the size of the isolator circuit 80, it is desirable to provide the CLK signal transmission section 60 and thereby to transfer the CLK signals generated by the same CLK oscillator to the XOR elements 41 and 43 as shown in the second embodiment.

Note that the CLK oscillator 61 may be disposed on the secondary side instead of being disposed on the primary side as in the case of the second embodiment. In such a case, the CLK signal output by the CLK oscillator 61 is input to the XOR element 43. The CLK signal transmission section 60 supplies the CLK signal to the XOR element 41 by transferring the CLK signal output by the CLK oscillator 61 from the primary side to the secondary side. Details of the above-described feature are similar to those of the second embodiment, and therefore their explanation is omitted.

If desired, the signal transmission in the isolator circuit 80 shown above in the second embodiment maybe implemented by using a single-end configuration rather than the differential signal configuration shown in FIG. 5. When the noise on the signal H is negligible, the LPF 44 and the Schmitt buffer 45 may be omitted. The other part of the configuration of the isolator circuit 80 may be also modified as appropriate, provided that the differential signal components D1 and D2 are converted into a single-end signal by using the above-described hysteresis comparators and the differential-single conversion buffer.

In the isolator circuit 80, the single-end signal is converted into the differential signal by the buffer 46 and the inverter 47. Then, the differential signal is converted into edge signals and transferred to the secondary side by the capacitive isolators 48 and 49. However, it is also possible to employ such a configuration that: an single-end signal encoded by the XOR element 41 is converted into an edge signal and the edge signal is transferred to the secondary side by a capacitive isolator; and then the transferred edge signal is converted into a differential signal by a differential conversion unit including a buffer and an inverter.

Although the DC signal is transferred by performing Manchester encoding and decoding in the isolator circuit 80, the DC signal may be transferred by using other encoding methods. That is, the isolator circuit 80 may perform encoding by using an element(s) other than the XOR element.

Instead of the DC signal, an AC digital signal may be transferred as the digital input signal IN of the isolator circuit 80. In such a case, there is no need to perform Manchester encoding. Therefore, there is no need to provide the XOR elements 41 and 43 and the CLK signal transmission section 60 shown in FIG. 5. Note that “AC digital signal” means a signal having discrete values such as binary values consisting of “1” and “−1” and ternary values consisting of “1”, “0” and “−1”.

In the isolator circuit 80, each of the capacitive isolators 48, 49, 64 and 65 may be an isolator using other principles. For example, the second embodiment can be applied to an isolator using transformer coupling.

The first and second embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A signal conversion circuit comprising:
a first hysteresis comparator configured to receive a differential signal having first and second input signal components, to compare in magnitude between voltages of the first and second input signal components, and to output the comparison result as a first output signal;
a second hysteresis comparator configured to receive the first and second input signal components, to compare in magnitude between the voltages of the first and second input signal components, and to output the comparison result as a second output signal that is an inversion signal of the first output signal; and
a conversion buffer configured to convert the first and second output signals into a single-end signal.

2. The signal conversion circuit according to claim 1, wherein the first and second hysteresis comparators compare in magnitude the voltage of the first input signal component with the voltage of the second input signal component based on a first threshold voltage and a second threshold voltage lower than the first threshold voltage.

3. The signal conversion circuit according to claim 1, wherein the first input signal component is input to a noninverting input terminal of the first hysteresis comparator and the second input signal component is input to an inverting input terminal of the first hysteresis comparator, and
the second input signal component is input to a noninverting input terminal of the second hysteresis comparator and the first input signal component is input to an inverting input terminal of the second hysteresis comparator.

4. The signal conversion circuit according to claim 1, wherein the first and second hysteresis comparators and the conversion buffer are formed by transistors.

5. The signal conversion circuit according to claim 1, wherein the conversion buffer comprises:
a phase inversion unit configured to generate and output an inversion signal whose phase is reversed from that of the second output signal;
a buffer unit configured to generate and output a third output signal according to the first output signal and the inversion signal output by the phase inversion unit, the third output signal being substantially in phase with the second output signal; and
an inverter unit configured to generate and output the single-end signal obtained by inverting the third output signal.

6. The signal conversion circuit according to claim 5, wherein in the conversion buffer, at least one of the phase inversion unit, the buffer unit, and the inverter unit comprises a CMOS circuit in which a PMOS transistor is connected on a power supply voltage side and an NMOS transistor is connected on a ground side.

7. The signal conversion circuit according to claim 1, wherein the first and second hysteresis comparators and the conversion buffer are driven by a common driving power supply.

8. An isolator circuit comprising:
a primary-side circuit;
a secondary-side circuit including the signal conversion circuit according to claim 1; and
an isolator configured to transfer a signal from the primary-side circuit to the secondary-side circuit and to electrically isolate the primary-side circuit from the secondary-side circuit.

9. The isolator circuit according to claim 8, wherein
the primary-side circuit further comprises a conversion unit configured to convert an input single-end signal into a differential signal having first and second signal components and to output the first and second signal components, and
the isolator transfers the first and second input signal components to the signal conversion circuit based on the first and second signal components.

10. The isolator circuit according to claim 8, wherein the secondary-side circuit further comprises a conversion unit configured to convert a single-end signal transferred from the isolator into the differential signal having the first and second input signal components and to output the first and second input signal components to the signal conversion circuit.

11. The isolator circuit according to claim 8, wherein
the isolator circuit is configured to transfer a transmission signal from the primary-side circuit to the secondary-side circuit,
the primary-side circuit comprises an encoder configured to generate a signal to be input to the isolator by encoding the transmission signal into Manchester code, and
the secondary-side circuit comprises a decoder configured to decode the single-end signal output from the signal conversion circuit to the transmission signal.

12. The isolator circuit according to claim 11, wherein
the encoder encodes the transmission signal into Manchester code by using an input clock signal, and
the decoder decodes the single-end signal to the transmission signal by using the input clock signal.

13. The isolator circuit according to claim 12, wherein the isolator circuit further comprises a clock signal transmission unit configured to transfer and supply the clock signal input to the encoder to the decoder, or to transfer and supply the clock signal input to the decoder to the encoder.

14. The isolator circuit according to claim 11, wherein each of the encoder and the decoder comprises an exclusive-OR operation circuit.

15. The isolator circuit according to claim 8, wherein the isolator comprises a capacitive element.

16. A signal conversion method comprising:
outputting, as a first output signal, a result of a magnitude comparison between voltages of first and second input signal components of a differential signal;
outputting, as a second output signal that is an inversion signal of the first output signal, a result of a magnitude comparison between the voltages of the first and second input signal components; and
converting the first and second output signals into a single-end signal.
